(19) United States
(12) Patent Application Publication
(10) Pub. No.: US 2021/0280248 A1
(43) Pub. Date: Sep. 9, 2021

(54) OPTICALLY-ENABLED SERVER WITH CARBON NANOTUBES-BASED MEMORY

(71) Applicant: Honeycomb Secure Systems, Inc., Guntersville, AL (US)

(72) Inventor: Richard D. Ridgley, South Riding, VA (US)

(73) Assignee: Honeycomb Secure Systems, Inc.

(21) Appl. No.: 17/194,247

(22) Filed: Mar. 6, 2021

Related U.S. Application Data
(60) Provisional application No. 62/986,716, filed on Mar. 8, 2020.

(51) Int. Cl. G11C 13/02; B82Y 10/00; H05K 7/14

(52) U.S. Cl. CPC G11C 13/025; H05K 7/1494; H05K 7/1492; B82Y 10/00

(57) ABSTRACT

Embodiments directed at the design of an optically-enabled server based on using carbon nanotube based non-volatile memory and eliminating hard drives and/or solid-state drives. The disclosed optically-enabled server houses a plurality of blade servers connected to one another via high-speed optical interconnects instead of copper-based interconnects. In some embodiments, the high-speed optical interconnects include an optical interface generated from mating an electrical mezzanine connector included within an input/output interconnect module with corresponding mezzanine slots located on the motherboard of a blade server such that the optical interface provides the optical pathways for routing optical signals (between the plurality of blade servers and one or more external devices) generated using light of multiple wavelengths. In some embodiments, the disclosed design advantageously provides a 100-fold speed advantage over a single conventional optical blade edge server and a 3-fold energy savings over standard DDR4 Synchronous Dynamic Random-Access Memory (SDRAM) memory of the same size.

### CROSS-REFERENCE TO RELATED APPLICATIONS

This application claims priority to U.S. Provisional Application Number 62/986,716 filed Mar. 8, 2020, which is incorporated herein by reference in its entirety.

### TECHNICAL FIELD

The present disclosure relates to high-density, high-efficiency, optically-enabled servers, and the components included therein. Specifically, disclosed embodiments utilize carbon nanotubes (CNTs) in the design of an optically-enabled blade server.

### BACKGROUND

Businesses handling large data generally need higher computing power and memory to organize and process the data. Also, businesses processing high volumes of data use high-powered, low-cost computing modules that can be configured to perform specific processing tasks. These requirements have led to the emergence of technology related to aggregating and/or consolidating multiple computing modules or blade servers. A blade server is a self-contained computing device designed for a specific data processing task, such as high-density data storage. Typically, a blade server includes at least two processors and solid-state memory mounted on a single printed circuit board (PCB), often called a motherboard. Multiple blade servers are housed within a blade enclosure. The blade enclosure may include power supplies, cooling fans, electrical power connections, optical network data interconnections, and peripheral I/O devices communicating with the blade servers. In many instances, a data center can include blade servers and their associated enclosures placed within a rack. By increasing density and reducing cable lengths in each rack, a data center can accommodate hundreds or thousands of blade servers, called a hyperscale data center. However, conventional blade servers face several challenges. For example, network data interconnections provided by blade enclosures to the individual blades have been significantly slow and have failed to provide the optimal, high-speed optical data rate needed to meet current business needs. Furthermore, high-speed volatile memory included in blade servers consume significant amounts of power, which requires installing cooling units for thermal dissipation, which leads to added equipment costs and reduced operational efficiencies.

### BRIEF DESCRIPTION OF THE DRAWINGS

The accompanying drawings illustrate various embodiments of the principles described herein and are part of the specification. The illustrated embodiments are merely examples and do not limit the scope of the claims.

FIG. 1 shows a perspective front view of an illustrative blade enclosure populated with individual optical blade servers.

FIG. 2 shows a perspective rear view of an illustrative blade enclosure populated with fans, power supplies, optical interconnect modules.

FIG. 3 shows details of an illustrative optical blade server.

FIG. 4 shows details of an illustrative high-speed optical interconnect module (ICM).

FIG. 5 illustrates an example of a high-speed optical network adapter module included within an optical blade server.

FIG. 6 illustrates a non-volatile memory module based on carbon nanotube memory cells within non-volatile CNT based memory chips.

FIG. 7 illustrates example high-speed data flow between an optical enabled midplane and an ICM located at the rear of an enclosure shown in FIG. 2 and optical blade servers at the front of an enclosure shown in FIG. 1.

FIG. 8 illustrates an example mezzanine connector included within an optical network adapter module.

FIG. 9 illustrates example inter-connections between an optical network adapter module input and output and an optically-enabled midplane within an enclosure.

### DETAILED DESCRIPTION

Embodiments of the present technology are directed at the design of a high-density, high-efficiency, optically-enabled server, and the components included therein. According to disclosed embodiments, the optically-enabled server can include a plurality of blade servers comprising non-volatile carbon nanotubes (CNT) based memory modules instead of traditional volatile silicon-based transistor and capacitor Dynamic Random Access Memory (DRAM). Replacing traditional volatile silicon-based memory with carbon nanotube based non-volatile memory results in at least a 3-fold energy savings over standard DDR4 Synchronous Dynamic Random Access Memory (SDRAM) memory of the same capacity. Further, the miniaturized CNTs enable improvements in processing density of the memory. For example, using 14 nm photolithography, CNT memory chips with storage capacities ranging between 16 Gigabit to 128 Gigabit can be obtained. A high-density, high-efficiency, optically-enabled server (a/k/a optical server) includes high-speed input and output optical network interface modules for providing external optical network 100 Gbps or 200 Gbps optical data streams to the optical blade servers.

The disclosed optical server also includes an optical network adapter module that is designed according to a form factor to fit within the space of an optical blade server (alternatively termed herein as “blade server”) and provide optical network connectivity by interfacing with an optically-enabled midplane included within an enclosure housing multiple optical blade servers. The optically-enabled midplane allows an optical blade server to be connected (e.g., to facilitate east-west Layer 2 traffic) directly to other components within the optical server chassis, and to other optical servers located within other server racks.

In some embodiments, the interfacing between the optical network adapter module and the optically-enabled midplane is based on using mezzanine connector slots within an optical blade server. Additionally, the disclosed optical blade server utilizes multiple optical interconnect modules (ICMs) located at the rear of the optical server to provide high-speed, non-blocking, optical connections between each blade server and external devices/networks (such as optical switches and/or high-speed networks). In some embodiments, the disclosed designs are based on using optical interconnects instead of copper-based interconnects. This can provide substantial energy savings, increased performance, and enhanced security.

In some embodiments, the designs disclosed herein eliminate hard drives and/or solid-state drives within an optical server. By eliminating use of hard drives and solid-state drives, advantageously, at least a 100-fold speed advantage over a single state-of-the-art blade server can be realized. In contrast to conventional designs, the disclosed designs utilize an optically-enabled midplane and/or an optically-enabled back plane that allow the optically-enabled server to be connected directly to other devices within a server chassis, and externally between racks of servers through optical connections for purposes of Layer 2 east/west data traffic. Thus, unlike a rack server which is an independent server within racks, the disclosed technology entails utilizing a collection of modular blade servers working with each other and housed inside a single chassis/enclosure.

In one aspect, the disclosed high-speed, optical blade server design enables additional space to be created on the motherboard for increased airflow and cooling. In one aspect, the disclosed high-speed optical server design can be configured to operate at ambient temperatures less than or equal to 80° Celsius. In one aspect, the disclosed high-speed optical server design using CNT-based memory is immune to ionizing radiation by virtue of CNTs being immune to effects of such radiations.

As used in this document, the singular forms “a,” “an,” and “the” include plural reference unless the context clearly dictates otherwise. Unless defined otherwise, all technical and scientific terms used herein have the same meanings as commonly understood by one of ordinary skill in the art. All publications mentioned in this document are incorporated herein by reference. All sizes recited in this document are by way of example only, and the disclosure is not limited to structures having the specific sizes or dimensions recited below.

The term “server” refers to the name given to any device and computer program that provides functionality for other programs or devices. This architecture commonly referred to as the client-server model, provides for a single overall computation to be distributed across multiple processes or devices. Servers can provide various functionalities, often called “services”, such as sharing data or resources among multiple users or performing computation for a client. A single server can serve multiple clients, and a single client can use multiple servers. A client process may run on the same device or may connect over a network to a server on a different device. Examples of a server include, but are not limited to: Application Server, Collaboration Server, Database Server, Edge Server, File Server, FTP Server, Game Server, Mail Server, Print Server, Windows server, Proxy Server, Real-Time Communication Server, Server Platforms, Web Server, etc.

The term “carbon nanotube” (CNT) refers to a honeycomb lattice rolled into a cylinder. The diameter of a carbon nanotube is of nanometer size and the length of the nanotube can be more than 1 μm. One of the significant physical properties of carbon nanotubes is their electronic structure which depends only on their geometry. Carbon nanotubes (CNTs) are composed of pure carbon in which atoms are positioned in a cylindrical form that exhibit novel properties that make them ideally useful in a wide variety of electronic and optical and physical applications. Single-wall CNTs (SWNTs) can be isolated and oriented, as is the case in CNT nonvolatile memory, to construct extremely dense switches, or used as trace materials on PCBs (either as SWNTS or as SWNT-bundles) to create extremely low impedance interconnects between components. In the case of memory, CNTs enable dramatic reduction in energy demand, 2- to 8-fold increase in storage density, greater reliability, instant on/off, perpetual storage of data, and no soft errors that are common to SDRAM. CNTs are inert to ionizing radiation, and so are radiation immune and well-suited for use in space-related applications. When CNTs are used in designing non-volatile memory, CNT-based memory provides high electrical and thermal conductivity. The thermal conductivity of CNTs makes them well-suited for thermal management (e.g., planar heat dissipation) for electronic devices, reducing the need for active cooling in most devices made therefrom.

The term “printed circuit board” (PCB) refers to the mechanical support and electrical connection of electronic components, or electrical components using conductive tracks, pads and other features etched from one or more sheet layers of a laminated substrate onto and/or between sheet layers of a non-conductive substrate. Components are generally soldered or adhesively bonded onto the PCB to both electrically connect and mechanically fasten them the components to the PCB. Printed circuit boards are used in most electronic products. PCBs can be single-sided, double-sided, or multi-layer. Multi-layer PCBs allow for much higher component density because circuit traces on the inner layers would otherwise take up surface space between components. For purposes of the disclosed technology, multilayer PCBs are considered having more than four trace planes incorporating surface mount technology.

The term “optical interconnect” refers to any system of transmitting and receiving optical signals from one part of an integrated circuit to another using light. Embodiments of the present disclosure provide the successor to electrical interconnects in order to address current and forthcoming needs for the transfer of large data volumes in constantly growing data centers and high-end computing systems. For purposes of this document, the term “optical interconnects” refers to high-speed optical connection into and out of network interface cards or optical network adapter modules mounted in server modules.

The term “module” can be regarded as generally synonymous with the term “card.” Thus, for example, a memory module and a memory card are used interchangeably.

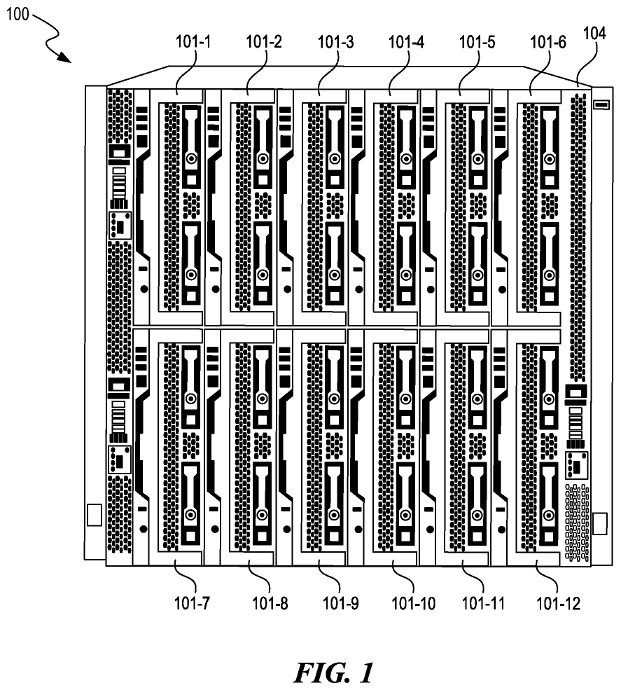

Referring to FIG. 1, a front view of an illustrative optical server (100) is shown. The optical server (100) includes an enclosure (104) that houses multiple optical blade servers (such as blade servers (101-1 to 101-12), power supply units, network input/output (I/O) cards, cooling fans, administration modules, and other units. (The terms “enclosure” and “housing” are used interchangeably throughout this disclosure.) Blade servers (101-1 to 101-12) and several other components of the optical server (100) can be regarded as “hot swappable.” A hot swappable blade server permits replacement or addition of a given blade server without stopping, shutting down, rebooting, or otherwise affecting the operation of one or more other optical blade servers working in conjunction with the enclosure (104). In some embodiments, the enclosure (104) of the optical server (100) may be designed according to half-high specifications, creating two rows of six optical blade servers, such that blade servers (101-1 to 101-6) are arranged in a first row and blade servers (101-7 to 101-12) are arranged in a second row. Typically, each of the blade servers has the same width and depth dimensions based on the respective needs of the data systems in which the blade servers are to be used. The number of blade servers shown in FIG. 1 are merely for illustration purposes. In alternate embodiments of the present disclosure, an optical server can include any number of blade servers arranged in any suitable number of rows.

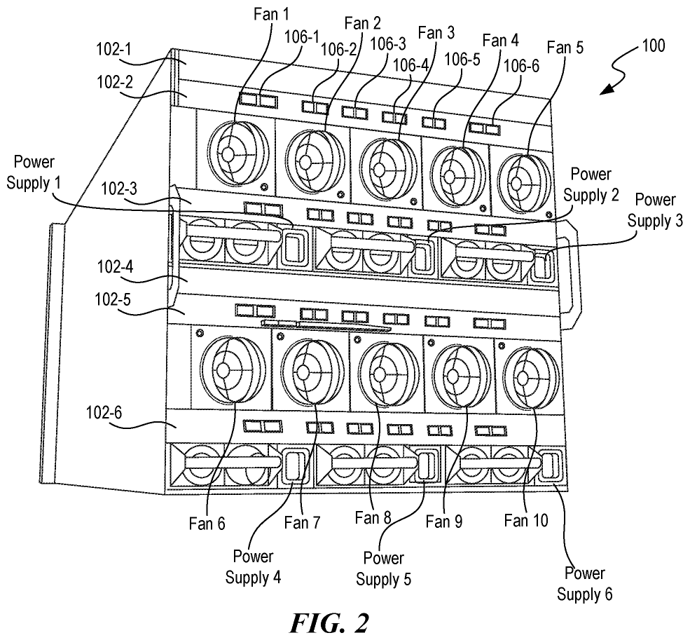

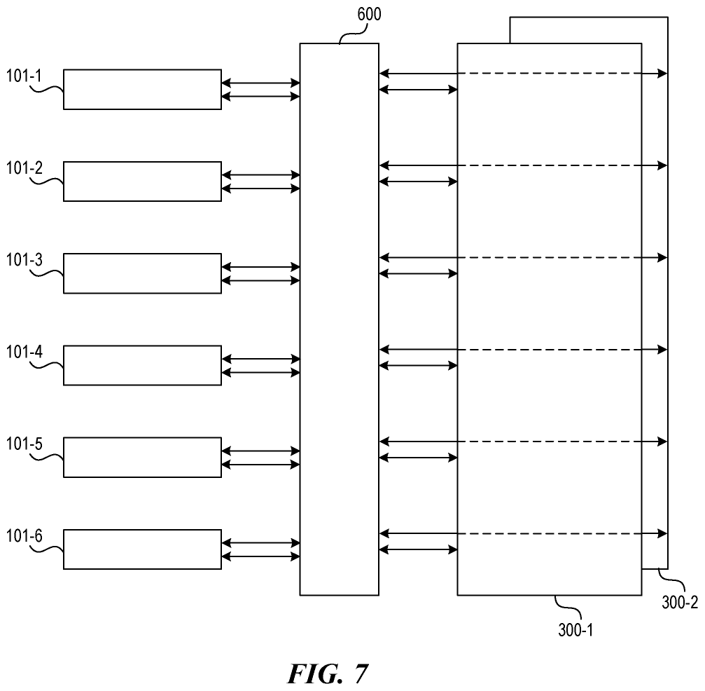

Referring to FIG. 2, the rear portion of an illustrative optical server (100) is shown. The rear portion of the enclosure (104) can include fans (such as fans 1-10), multiple network input/output interconnect modules (ICMs) (such as ICMs 102-1 to 102-6), one or more power supplies 1-6, and redundant administrator modules. In some embodiments, the ICMs may be configured to provide optical pathways for routing optical signals generated using light of multiple wavelengths between the plurality of optical blade servers (within the optical server (100)) and devices/networks/switches located external to the optical blade servers. The ICMs 102-1 to 102-6 are passive optical pass throughs from an optically-enabled midplane (such as optically-enabled midplane 600 shown in FIG. 7) and optical ports 106-1 to 106-6 located at the rear of the optical server (100). In some embodiments, one row of optical blade servers (e.g., row 101-1 to 101-6 or row 101-7 to 101-12) is supported by a minimum of two ICMs (300).

FIG. 2 shows a set of ports (106-1 to 106-6) included on ICM 102-2 for allowing optical data transfers between an optical blade server (or, simply a “blade server”) and an external optical network or a switch. In some embodiments, one or more ports can support a data rate of 100 Gbps or 200 Gbps. In some embodiments, the 100 Gbps or 200 Gbps ports can be on the same ICM, with all ports on each ICM having the same data rate.

In some embodiments, an ICM may include at least two computer processors, such as a first microprocessor and a second microprocessor. Each administrator module may include at least one processor configured to perform instructions stored in memory on the administrator module. The administrator modules may be configured to communicate (e.g., send/receive instructions and/or data) internally with one or more optical blade servers and other components inside the optical server.

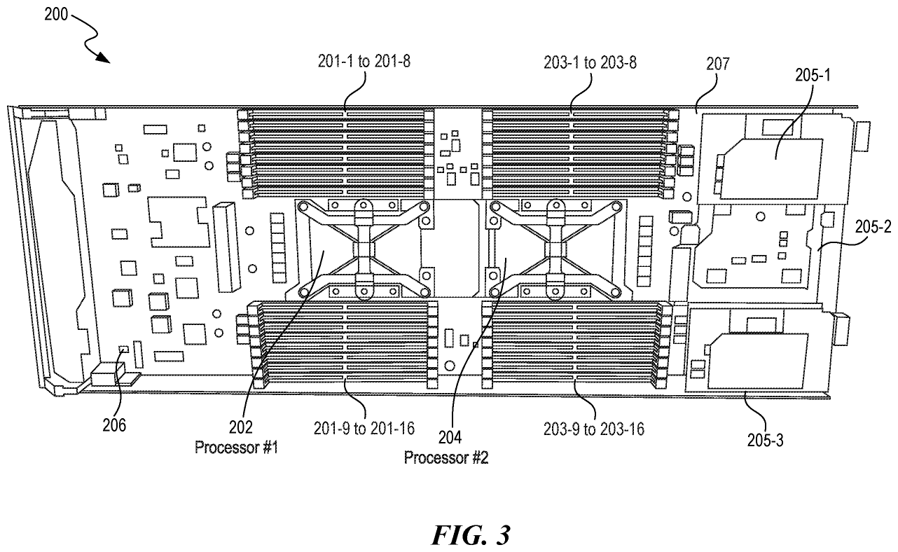

FIG. 3 shows illustrative details of an example optical blade server (200) consistent with the present disclosure. The blade server (200) (a/k/a compute module) includes printed circuit board (PCB) (207) that supports input/output network interface adapter modules (205-1 to 205-3) and an unpopulated portion 206, which, on a non-optical blade server would be used to house two hard disk drives or two solid-state drives. The input/output network interface adapter modules (205-1 to 205-3) are optical network adapter cards, each of which takes an electrical 3×16 lane PCIe bus and converts it into a high-speed 100 Gbps or 200 Gbps optical data stream. The conversion of optical signals into electrical signals applies to in-bound signals and the conversion of electrical signals to optical signals applies to out-bound optical signals. According to disclosed embodiments, the input/output network adapter modules (205-1 to 205-3) include mezzanine electrical connectors for interfacing with a 3×16 lane PCIe bus from microprocessors (202 and 204). The mezzanine connector enables physical and electrical coupling between an optical network adapter module and a blade server. The unpopulated portion (206) is devoid of a hard disk drive or solid-state drive cage. Thus, at least one advantage of the present technology is that hard drives or solid-state drives are eliminated, providing increased airflow and thermal dissipation. FIG. 3 shows up to sixteen (16) sets of memory slots (201-1 to 201-16) and (203-1 to 203-16) supported on the PCB (207) (alternatively termed herein as “motherboard”). For example, memory slots (201-1 to 201-16) and (203-1 to 203-16) can support DDR4 memory DIMMs. According to disclosed embodiments, the DDR4 memory DIMMs can comprise non-volatile CNT-based random-access memory (alternative termed “NRAM”). For example, the CNT materials (defined and etched by photolithography) can be located between two metal electrodes and forms the NRAM cell, which constitute an array of CNT memory cells within a NRAM non-volatile memory chip. Then these CNT memory chips are placed onto a memory module (500). One or more processors (such as processor #1 denoted (202) and processor #2 denoted (204) can be included on the PCB (207). In contrast to conventional servers, in which the operating system, driver software, and user applications are loaded on hard drives or solid-state drives, the present technology is directed at storing the operating system, driver software, and user applications on non-volatile CNT-based memory.

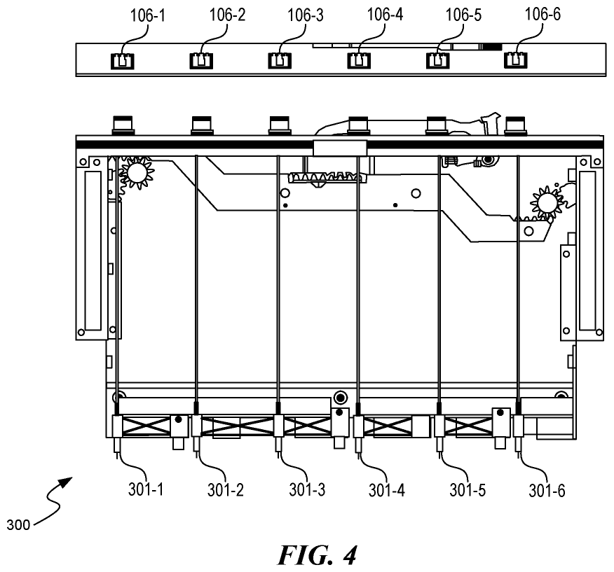

Referring now to FIG. 4, a perspective top view of an interconnect module (ICM) (300) is shown. Generally, an ICM (such as ICM (300)) can provide optical pathways for routing optical signals between a blade server (located within an optical blade server (200)) and devices/networks/switches located external to the ICM (300). In some embodiments, the ICM (300) is inserted in the rear of a blade enclosure (104) of optical server (100) and functions as a passive optical interface for facilitating high-speed optical data transfer from/to external networks. Each ICM (such as ICM (300)) can include multiple blind-mate connectors (such as 301-1 to 301-6) located on the rear side of ICM (300) to facilitate data transfer to external optical networks. For example, blind-mate connectors (301-1 to 301-6) provide high-speed passive optical pass-through between an optically-enabled midplane (such as optically-enabled midplane (600) shown in FIG. 7 of the enclosure (104)) and input/output network interface modules (205-1 to 205-3) located within each optical blade server. In this embodiment, the ICM (300) can function as a 100 or 200 Gbps pass-through module for applications with a high-speed optical non-blocking, one-to-one connection between each blade and an external high-speed optical network or an optical switch. Thus, a subset of the blind-mate connectors (301-1 to 301-6) can support data transfers at both 100 Gbps or 200 Gbps. For example, in such an embodiment, each enclosure (104) can include at least a total of four ICMs supporting two rows of blade servers, with six blade servers in each row with two of the ICMs supporting both 100 Gbps or 200 Gbps data rate. In these embodiments, only optical cables and connectors are supported. No copper-based cables or connectors are supported.

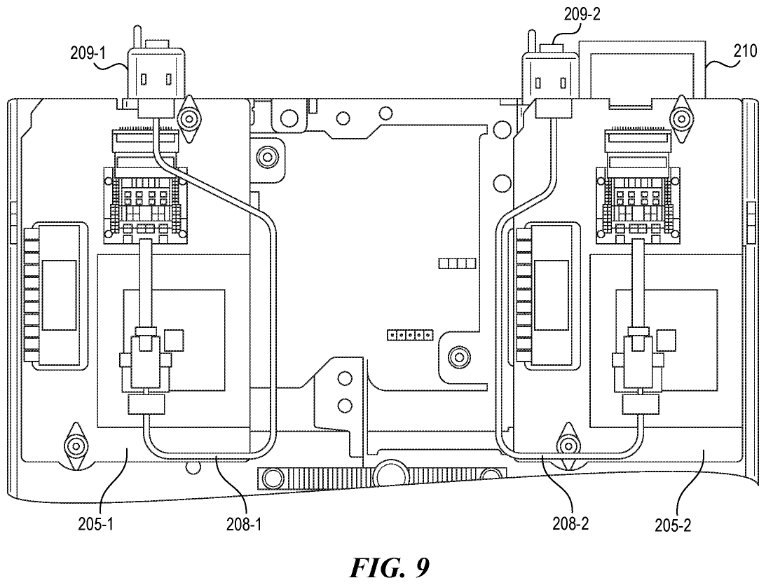

In some exemplary embodiments, each optical blade server (200) includes two optical blind-mate connectors (209-1 and 209-2 shown in FIG. 9) coupled to two different ICMs (300), such that each optical blind-mate connector is coupled to all optical blade servers and connected to an ICM (300) via the optically-enabled midplane (600) within enclosure (104). Further, each optical blind-mate connector supports 100 Gbps or 200 Gbps optical data. Each optical pathway is composed of 32 bi-directional optical lanes. If a first wavelength (A) of light is used per optical fiber lane at 25 Gbps per wavelength, this can achieve 1.6 Terabit per second (Tbps) per blade. If four different wavelengths of light are used per optical pathway each supporting data rates of 50 Gbps per wavelength, this can achieve up to a maximum of 12.8 Tbps per blade. For an optical server frame comprising twelve blade servers, a maximum of 153.6 Tbps per optical server can be realized. On the contrary, conventional servers at best support 50 Gbps rates for data connections. Thus, one advantage of the present technology is that over a 100-fold performance improvement in data rates can be realized over a single optical blade server.

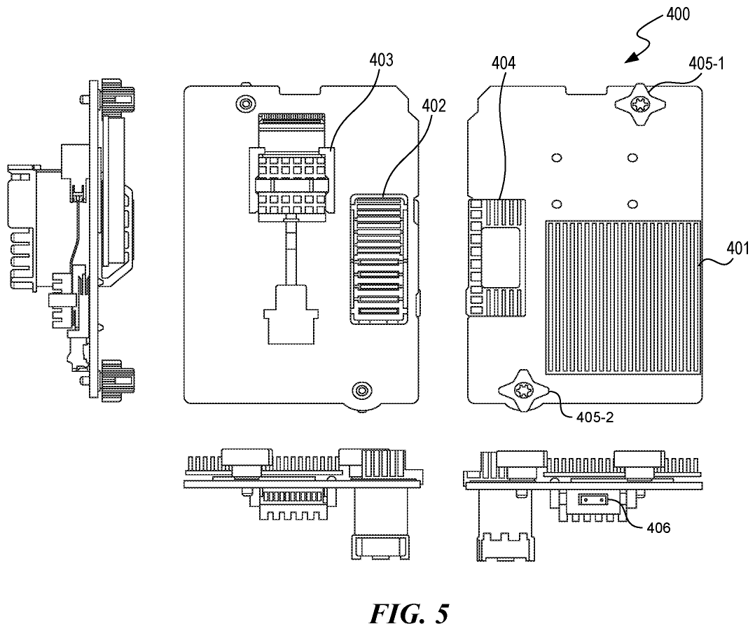

FIG. 5 illustrates an optical network adapter module (400). This module (included within an optical blade server (200)) enables conversion of electrical signals to optical signals for high-speed optical data communications. The optical network adapter module (400) includes a mezzanine electrical connector (402), an optical transceiver (403), a depressible portion (404), an optical connector (406), and retaining screws (405-1 and 405-2). In some embodiments, the mezzanine electrical connector (402) connects electrically to the motherboard (207) via the 3×16 lane PCIe bus and the mezzanine electrical connector (402) also connects to the optically-enabled midplane (600) shown in FIG. 7. Thus, one connection of the mezzanine electrical connector (402) is electrical and the other connection is optical.

It will be appreciated that the optical network adapter module (400) is different from a conventional optical network adapter module. For example, the optical network adapter module (400) does not include a PCIe connector for a PCIe slot, which is typically present in a conventional optical network adapter module. According to disclosed embodiments, in place of the PCIe connector, the mezzanine electrical connector (402) is used. The mezzanine electrical connector (402) located on the optical network adapter module (400) is designed to mate/align/interface with mezzanine connector slots (such as slots located on input/output network adapter modules (205-1 to 205-3) located on the motherboard of an optical blade server (200) shown in FIG. 3). The mating of the mezzanine electrical connector (402) with the mezzanine connector slots is achieved by pressing the depressible portion (404) and tightening the screws (405-1 and 405-2) on the optical network adapter module (400). Further modifications of a conventional optical network adapter module include replacing the copper-based electrical input and output connectors in a conventional optical network adapter module with an optical transceiver (403) and an optical connector (406), i.e., copper-based interconnects are replaced with passive optical interconnects. The optical transceiver (403) is inserted into an optically-enabled mid-plane (600) FIG. 7 and serves as an output of an optical blade server. According to disclosed embodiments, due to limited space available inside an optical blade server, the PCB supporting the optical network adapter module (400) has a physical form factor amenable to fit inside a blade server (200). Advantageously, the disclosed high-speed optical adapter (400) alleviates CPU (202 and 204) utilization, increases the number of virtual machines (VMs) placed on each blade server, and improves cloud scale efficiency. The disclosed high-speed optical adapter (400) is designed to be 100% compatible with conventional servers having high-density 100 Gbps or 200 Gbps Ethernet optical switching solutions, i.e., the disclosed optical network adapter module (400) provides high throughput, low latency, and increased scalability.

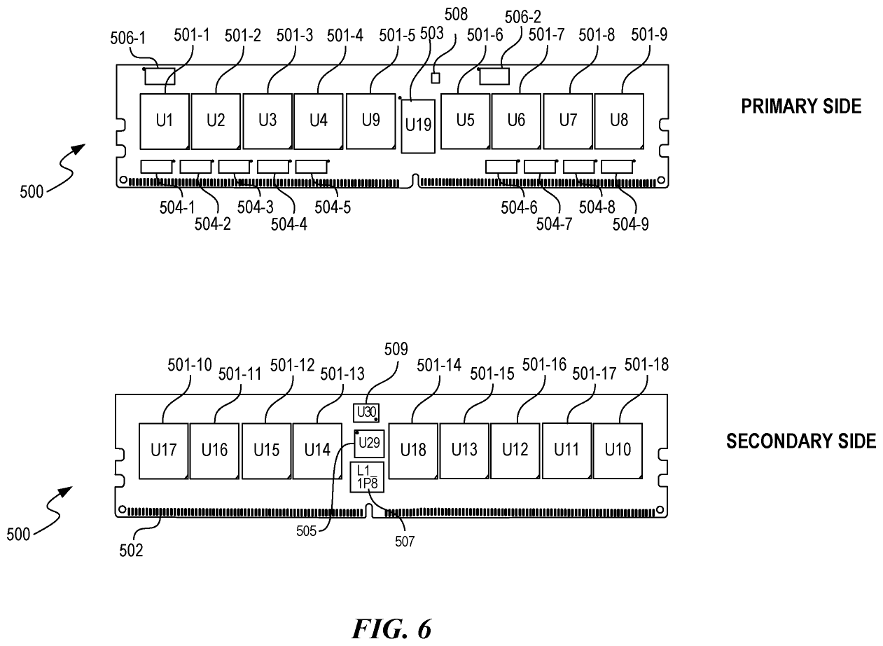

Referring now to FIG. 6, a primary side and a secondary side of a DDR4 dual in-line memory module (DIMM) (500) is shown. According to disclosed embodiments, the DIMM (500) utilizes non-volatile NRAM carbon nanotube (CNT) based multi-gigabit memory chips (501-1 to 501-18). The DIMM (500) (compliant with JEDEC DDR4 or DDR5 standards) plugs into memory slots (201-1 to 201-16) and (203-1 to 203-16) located within an optical blade server (200). For example, the DIMM (500) can be inserted into slots (201-1 to 201-8, 201-9 to 201-16, 203-1 to 203-8, and 203-9 to 203-16) of blade server (200) shown in FIGS. 3. U1 to U18 represent the CNT-based non-volatile multi-gigabit memory chips. In some embodiments, the CNT-based memory module (500) comprises 128 GB, 256 GB, or 512 GB storage capacity. For example, such memory can be configured to operate at 2666, 2933, and 3200 Million transfers per second (MT/s) speed, compliant with IAW JEDEC DDR4 or DDR5 specifications for servers, desktops, and PCs.

The disclosed non-volatile DIMM (500) (e.g., includes 288 pins) is compatible with traditional volatile DIMMs. Current state-of-the-art (SOTA) blade servers or compute modules typically use volatile Synchronous Dynamic Random-Access Memory (SDRAM) multi-gigabit memory requiring a hard disk drive or solid-state drive to retain the computer processing units operating system and other component drivers. Several advantages of the disclosed CNT-based memory are as follows:
CNT-based memory consumes 3× lower power than SOTA SDRAM memory.
CNT-based memory is not subjected to soft errors (e.g., arising from radiation in space or terrestrial radiation), making them well-suited for use in applications for space. Soft errors typically occur due to collisions between high-energy neutrons and silicon atoms constituting a SDRAM memory chip. Thus, by eliminating soft errors, CNT-based memory is exempt from temporary surges in current and exempt from accidental changes to the data values stored in the memory. The soft error rate can depend on the design/orientation of the bit lines included in the CNT based memory.
CNT-based memory is deterministic and does not require refreshing unlike SDRAM.
CNT-based memory is scalable below 5 nm photolithography (e.g., associated with extreme ultra violet photolithography).
CNT-based memory can universally replace different types of memory. For example,
CNT-based memory can replace SRAM, SDRAM, and 3D NAND flash memory. As another example, a 6 transistor SRAM memory cell can be replaced with a single CNT molecular microswitch.
Because non-volatile memory freezes the state of the memory, CNT-based memory does not require checkpoints or restarts in applications involving high performance computing.
Load-Reduced dual in-line memory modules (LRDIMMs) associated with CNT-based memory is scalable, obviating the need for hard disk drives and solid-state drives, which eliminates the needs for SAS/SATA and NVMe buses.

In FIG. 6, the primary side of the DIMM module (500) shows data buffers (504-1 to 504-9), each data buffer serving two (2) CNT memory chips. Component (503) of the DIMM module (500) is a registering clock driver (RCD/PLL) for buffer control. Components (506-1 and 506-2) shown on the primary side of the DIMM module (500) represent voltage regulators. Component (508) is a serial presence detect (SPD) erasable programmable read-only memory (EPROM), e.g., having a size of 512 Bytes.

Referring to the secondary side indicated in FIG. 6, component (502) represents the pins (e.g., 288 pins) of the DIMM module (500). Components (505 and 509) are voltage regulators. Component (507) is an inductor operating at, e.g., 1.8 V.

In some embodiments, the NRAM memory chip (501-1 to 501-18) has four internal bank groups comprising four memory banks each, providing a total of 16 banks. This enables use of an 8n-prefetch architecture with an interface designed to transfer two data words per clock cycle at the I/O pins. A single READ or WRITE operation for the NRAM memory chips (501-1 to 501-18) effectively includes a single 8n-bit-wide, four-clock data transfer at the internal NRAM core and eight corresponding n-bit-wide, one-half-clock-cycle data transfers at the I/O pins. In some embodiments, the NRAM memory chip uses two sets of differential signals: DQS_t and DQS_c to capture data and CK_t and CK_c to capture commands, addresses, and control signals. Differential clocks and data strobes ensure exceptional noise immunity for these signals and provide precise crossing points to capture input signals. According to some embodiments, memory cells (e.g., storing one bit of information) are arranged in a two-dimensional array. For example, if the array is of size 8×8, then the total number of bits that can be stored is 64. Each carbon nanotube memory cell has a word line that acts to control the cell. The signal that accesses the cell to either read or write data is applied to the word line. Perpendicular to the word line are bit lines. The data that is written into, or read from the memory, is found on the bit lines.

This embodiment of DIMM module (500) uses faster clock speeds than earlier DDR technologies, making signal quality more important than ever. For improved signal quality, the clock, control, command, and address buses are routed in a fly-by topology, where each clock, control, command, and address pin on each NRAM memory chip is connected to a single trace and terminated (rather than a tree structure, where the termination is off the module near the connector). The fly-by topology accounts for the timing skew between the clock and DQS signals by using the write leveling feature of JEDEC DDR4 specification.

FIG. 7 illustrates a conceptual block diagram showing optical data flows between an optical enabled midplane (600) connected to optical blade servers (101-1 to 101-6) and ICMs (300-1 and 300-2) associated with the enclosure (104). Blade servers (101-1 to 101-6) are connected to ICMs (300-1 and 300-2) via the optically-enabled midplane (600) for exchange of bi-directional optical data at 100 Gbps or 200 Gbps per channel. The optically-enabled midplane (600) allows the optical blade server ((101-1 to 101-12), shown in FIG. 1) to be connected (e.g., to facilitate east-west Layer 2 traffic using the OSI terminology) directly to other external components outside the chassis/enclosure (104) of a single optical server, and to other optical servers located within server racks. For example, data is carried by high-speed optical signals generated using light of multiple wavelengths between the blade servers ((101-1 to 101-6), shown in FIG. 1), via the passive pass-through interconnect module (e.g., shown in FIG. 4) and external optical devices/networks. This high-speed data communication is bi-directional. Additionally, FIG. 7 shows that bidirectional optical data flow is exchanged between the optically-enabled midplane (600) and dual interconnect modules (300-1 and 300-2). The bidirectional optical data flow is represented using two sets of six each bidirectional optical data flow pathways, one set of six bi-directional optical pathways to a first ICM (such as ICM (300-1)) and a second set of six bi-directional optical pathways to a second ICM (such as ICM (300-2)). It will be appreciated that optical data exchanges between servers to optically-enabled midplane (shown on the left side of the midplane (600)) and midplane to ICMs (shown on the right side of midplane (600)) are bi-directional.

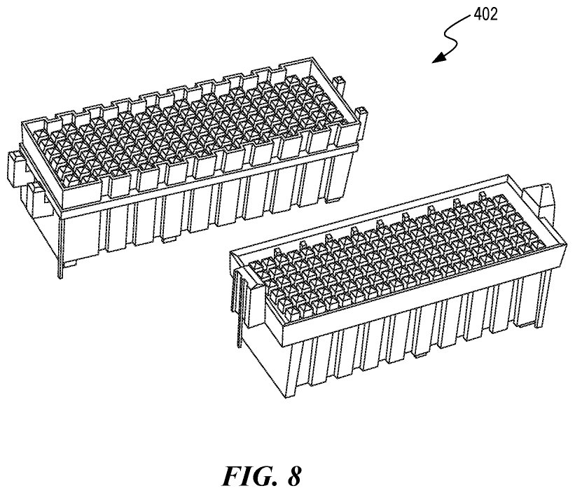

FIG. 8 illustrates an example electrical mezzanine connector (402). The electrical mezzanine connector (402) is included within an optical network adapter module (such as optical network adapter module (400) shown in FIG. 5). The electrical mezzanine connector (402) is used to interface with mezzanine slots on input/output network adapter modules (such as input/output network interface slots(205-1 to 205-3) included in blade server (200) shown in FIG. 3). According to disclosed embodiments, the electrical mezzanine connector (402) enables an optical network adapter module to fit within a blade server (200). As a result of using the electrical mezzanine connector (402), the optical network adapter module (400) can interface within an optically-enabled midplane (600) located inside the enclosure (104). For example, the pin and socket configuration of the electrical mezzanine connector (402) can facilitate a high-bandwidth connection (e.g., up to 200 Gbps) over a PCIe 4.0 3×16 lane connection from processors (such as processors (202) and (204) included in blade server (200) shown in FIG. 3).

FIG. 9 illustrates example inter-connections between an optical network adapter module (400) and an optically-enabled midplane (600). For example, FIG. 9 shows optical blind-mate connectors (209-1 and 209-2) located on a blade server (200). The term “blind-mate connectors” can be regarded as “self-aligning connectors.” For example, without visual inspection, blind-mate connectors (209-1 and 209-2) allow an ICM or a blade server to be plugged directly into the optically-enabled midplane.

The blind-mate connectors (209-1 and 209-2) line up with a set of blind-mate connectors that are located on an optically-enabled midplane (such as optically-enabled midplane (600) shown in FIG. 7) for connecting an optical network adapter module to the optically-enabled midplane (600). Component (210) shows the power connector. Cables (208-1 and 208-2) are optical fiber cables used for connecting an optical connector located on an optical network adapter module (such as optical connector (406) located on optical network adapter module (400) shown in FIG. 5) to blind-mate connectors (209-1 and 209-2) included in blade server (200) shown in FIG. 9). There is no limitation on optical connector (406). For example, any standard optical connector can be used.

Some embodiments of the disclosed technology are now presented in clause-based format.

1. A high-density, high-speed optical server comprising:
a housing enclosing a plurality of blade servers, each blade server comprising a plurality of carbon nanotube (CNT)-based non-volatile memory modules configured to be exempt from soft errors eliminating refresh, reboot, checkpoint, and restart operations, wherein a use of the CNT-based non-volatile memory modules includes eliminating a use of hard drives and/or solid-state drives; and
a plurality of input/output interconnect modules (ICMs) providing optical inputs and outputs for each blade server and positioned at a rear portion of the housing configured to provide optical pathways for routing optical signals between the plurality of blade servers and one or more external devices, the optical signals generated using light of multiple wavelengths,
wherein a blade server of the plurality of blade servers is connected to at least a pair of the plurality of ICMs via an optical interface generated from mating an electrical mezzanine connector included within an optical network adapter module with corresponding mezzanine slots located on a motherboard of the blade server such that the optical interface provides the optical pathways for routing the optical signals.

2. The optical server of clause 1, further comprising:
the optical network adapter module for enabling conversion of electrical signals to optical signals for high-speed optical data communications based on the optical interface generated from the mating of the electrical mezzanine connector with the corresponding mezzanine slots, wherein the optical network adapter module has a form factor that allows placement of the optical network adapter module within the blade server.

3. The optical server of clause 1, wherein the plurality of ICMs include a set of ports supporting data transfer at either 100 Gbps or 200 Gbps data rate.

4. The optical server of clause 3, wherein the CNT-based non-volatile memory modules are compliant with IAW JEDEC DDR4 or DDR5 specifications for servers, desktops, and PCs.

5. The optical server of clause 3, wherein the plurality of ICMs include at least four (4) ICMs such that the ICMs support either 100 Gbps data rate or 200 Gbps data rate.

6. The optical server of clause 1, wherein the plurality of blade servers is arranged in at least two rows within the housing, with a first set of blade servers included in a first row and a second set of blade servers included in a second row.

7. The optical server of clause 6, wherein the first set of blade servers and the second set of blade servers each include six blade servers.

8. The optical server of clause 1, wherein the CNT-based non-volatile memory modules are inserted into dual in-line memory module (DIMM) slots disposed on the motherboard of the blade server.

9. The optical server of clause 1, wherein the (CNT)-based non-volatile memory modules comprise 128 GB, 256 GB, or 512 GB storage capacity.

10. The optical server of clause 1, wherein the plurality of CNT-based non-volatile memory modules is designed in accordance with a fly-by topology, wherein a clock, a control, a command, and an address pin on each CNT-based non-volatile memory module is connected to a single trace and terminated.

11. The optical server of clause 1, wherein the optical server is immune to ionizing radiation based on one or more characteristics of the plurality of CNT-based non-volatile memory modules CNTs.

12. The optical server of clause 1, wherein the optical server includes optical interconnections for Layer 2 east-west data traffic inside the optical server, eliminating a use of copper-based interconnections.

13. The optical server of clause 1, wherein the optical server is configured to operate at ambient temperatures less than or equal to 80° Celsius.

14. The optical server of clause 1, wherein the plurality of CNT-based non-volatile memory modules are immune to effects of ionizing radiations.

15. The optical server of clause 1, wherein the one or more external devices includes optical switches and high-speed optical networks.

Some of the embodiments described herein are described in the general context of methods or processes, which may be implemented in one embodiment by a computer program product, embodied in a computer-readable medium, including computer-executable instructions, such as program code, and executed by computers in networked environments. A computer-readable medium may include removable and non-removable storage devices including, but not limited to, Read-Only Memory (ROM), Random Access Memory (RAM), compact discs (CDs), digital versatile discs (DVD), etc. Therefore, the computer-readable media may include a non-transitory storage media. Generally, program modules may include routines, programs, objects, components, data structures, etc. that perform particular tasks or implement particular abstract data types. Computer- or processor-executable instructions, associated data structures, and program modules represent examples of program code for executing steps of the methods disclosed herein. The particular sequence of such executable instructions or associated data structures represents examples of corresponding acts for implementing the functions described in such steps or processes.

Some of the disclosed embodiments may be implemented as devices or modules using hardware circuits, software, or combinations thereof. For example, a hardware circuit implementation may include discrete analog and/or digital components that are, for example, integrated as part of a printed circuit board. Alternatively, or additionally, the disclosed components or modules may be implemented as an Application Specific Integrated Circuit (ASIC) and/or as a Field Programmable Gate Array (FPGA) device. Some implementations may additionally or alternatively include a digital signal processor (DSP) that is a specialized microprocessor with an architecture optimized for the operational needs of digital signal processing associated with the disclosed functionalities of this application. Similarly, the various components or sub-components within each module may be implemented in software, hardware or firmware. The connectivity between the modules and/or components within the modules may be provided using any one of the connectivity methods and media that is known in the art, including, but not limited to, communications over the Internet, wired, or wireless networks using the appropriate protocols.

The foregoing description of embodiments has been presented for purposes of illustration and description. The foregoing description is not intended to be exhaustive or to limit embodiments of the present disclosure(s) to the precise form disclosed, and modifications and variations are possible in light of the above teachings or may be acquired from practice of various embodiments. The embodiments discussed herein were chosen and described in order to explain the principles and the nature of various embodiments and their practical application to enable one skilled in the art to utilize the present disclosure(s) in various embodiments and with various modifications as are suited to the particular use contemplated. The features of the embodiments described herein may be combined in all possible combinations of methods, apparatus, modules, systems, and computer program products.

What is claimed is:

1. A high-density, high-speed optical server comprising:
a housing enclosing a plurality of blade servers, each blade server comprising a plurality of carbon nanotube (CNT)-based non-volatile memory modules configured to be exempt from soft errors eliminating refresh, reboot, checkpoint, and restart operations, wherein a use of the CNT-based non-volatile memory modules includes eliminating a use of hard drives and/or solid-state drives; and
a plurality of input/output interconnect modules (ICMs) providing optical inputs and outputs for each blade server and positioned at a rear portion of the housing configured to provide optical pathways for routing optical signals between the plurality of blade servers and one or more external devices, the optical signals generated using light of multiple wavelengths,
wherein a blade server of the plurality of blade servers is connected to at least a pair of the plurality of ICMs via an optical interface generated from mating an electrical mezzanine connector included within an optical network adapter module with corresponding mezzanine slots located on a motherboard of the blade server such that the optical interface provides the optical pathways for routing the optical signals.

2. The optical server of claim 1, further comprising:
the optical network adapter module for enabling conversion of electrical signals to optical signals for high-speed optical data communications based on the optical interface generated from the mating of the electrical mezzanine connector with the corresponding mezzanine slots, wherein the optical network adapter module has a form factor that allows placement of the optical network adapter module within the blade server.

3. The optical server of claim 1, wherein the plurality of ICMs include a set of ports supporting data transfer at either 100 Gbps or 200 Gbps data rate.

4. The optical server of claim 3, wherein the CNT-based non-volatile memory modules are compliant with IAW JEDEC DDR4 or DDR5 specifications for servers, desktops, and PCs.

5. The optical server of claim 3, wherein the plurality of ICMs include at least four (4) ICMs such that the ICMs support either 100 Gbps data rate or 200 Gbps data rate.

6. The optical server of claim 1, wherein the plurality of blade servers is arranged in at least two rows within the housing, with a first set of blade servers included in a first row and a second set of blade servers included in a second row.

7. The optical server of claim 6, wherein the first set of blade servers and the second set of blade servers each include six blade servers.

8. The optical server of claim 1, wherein the CNT-based non-volatile memory modules are inserted into dual in-line memory module (DIMM) slots disposed on the motherboard of the blade server.

9. The optical server of claim 1, wherein the (CNT)-based non-volatile memory modules comprise 128 GB, 256 GB, or 512 GB storage capacity.

10. The optical server of claim 1, wherein the plurality of CNT-based non-volatile memory modules is designed in accordance with a fly-by topology, wherein a clock, a control, a command, and an address pin on each CNT-based non-volatile memory module is connected to a single trace and terminated.

11. The optical server of claim 1, wherein the optical server is immune to ionizing radiation based on one or more characteristics of the plurality of CNT-based non-volatile memory modules CNTs.

12. The optical server of claim 1, wherein the optical server includes optical interconnections for Layer 2 east-west data traffic inside the optical server, eliminating a use of copper-based interconnections.

13. The optical server of claim 1, wherein the optical server is configured to operate at ambient temperatures less than or equal to 80° Celsius.

14. The optical server of claim 1, wherein the plurality of CNT-based non-volatile memory modules are immune to effects of ionizing radiations.

15. The optical server of claim 1, wherein the one or more external devices includes optical switches and high-speed optical networks.
